(19) United States
(12) Patent Application Publication
(10) Pub. No.: US 2006/0292843 A1
(43) Pub. Date: Dec. 28, 2006

(54) Method for fabricating semiconductor device

(75) Inventors: Seung-Bum Kim, Kyoungki-do (KR); Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/323,525

(22) Filed: Dec. 29, 2005

(30) Foreign Application Priority Data
Jun. 28, 2005 (KR) 2005-0056409

(51) Int. Cl. H01L 21/465

(52) U.S. Cl. 438/586; 438/592; 438/738; 438/736

(57) ABSTRACT

Provided is a method for fabricating a semiconductor device, capable of increasing a contact open margin and minimizing a shoulder loss of a gate line. The method includes: forming a gate line on a substrate, the gate line including a first hard mask and a second hard mask; forming an inter-layer insulating layer over the substrate and the gate line; stacking a contact mask and an anti-reflective coating layer on the inter-layer insulating layer, the contact mask defining a contact region; and etching the contact mask and the anti-reflective coating layer until the first and second hard masks are exposed.

### FIELD OF THE INVENTION

The present invention relates to a method for fabricating a semiconductor device; and, more particularly, to a method for forming a landing plug contact of a semiconductor device.

### DESCRIPTION OF THE RELATED ART

As semiconductor devices have been integrated more highly, elements of the semiconductor device are formed in a stack structure. Accordingly, the concept of a contact plug (or pad) has been introduced.

In forming the contact plug, a landing plug contact (LPC) technology is generally used for increasing a contact area within a minimum area in a lower portion and increasing an operation margin with respect to subsequent processes in an upper portion. That is, an upper area is wider than a lower contacting area.

The LPC process can secure an overlay margin in a following contact process by previously filling a gap between gate patterns, where a bit line contact and a storage node contact have been formed, with a conductive material.

In forming the contact, it is difficult to etch between structures with high aspect ratio. Meanwhile, an SAC process is employed to obtain a specific etch profile using an etch selectivity between two materials (e.g., an oxide layer and a nitride layer).

In order to minimize an etch target during the SAC process, an inter-layer insulating layer is deposited and then a contact mask, a spacer and an inter-layer insulating layer are removed up to an upper portion of a gate hard mask through a planarization process, e.g., a chemical mechanical polishing (CMP).

Meanwhile, in the case of a direct nitride hard mask LPC etching process that is being applied to a device of 90-nm technology or less, there may be a “not-open” probability when a sufficient over-etching is not performed due to an unevenness between a gate hard mask nitride layer and an inter-layer insulating layer, a deposition of a nitride layer, and a thickness difference in an organic anti-reflective coating layer. If a sufficient over-etching is performed, an SAC margin is reduced due to a “shoulder broken” of the gate hard mask nitride layer, i.e., damage to a shoulder portion of the gate hard mask nitride layer.

FIGS. 1A to 1C are cross-sectional views for explaining a not open incidence in a conventional semiconductor device.

Referring to FIG. 1A, a gate line is formed by stacking a gate oxide layer 12, gate conductive layers 13 and 14, and a gate hard mask 15 on a semiconductor substrate 11 where a device isolation layer (not shown) is formed.

At this point, the gate conductive layers are provided with a stack structure of a polysilicon layer 13 and a silicide layer 14. The gate hard mask 15, which is formed of nitride is formed to 2,500 Å thick. However, the gate hard mask 15 of 2,100 Å thick remains after a gate patterning process.

Then, a CMP or etch-back process is performed to planarize the inter-layer insulating layer 16 by using the gate hard mask 15 as an etch target.

However, after the planarization, an indented portion is generated in the inter-layer insulating layer 16 between the gate lines due to a dishing event. The dishing event occurs when the gate line is over-etched in a wide contact hole region.

Then, an LPC hard mask nitride layer 17 and an organic anti-reflective coating layer 18 are deposited on an entire surface of the resulting structure. The LPC hard mask nitride layer 17 is deposited along the indented portion with step coverage. Since the organic anti-reflective coating layer 18 for the mask patterning is flowable, the inter-layer insulating layer 16 between the gate lines is thicker.

Referring to FIG. 1B, the organic anti-reflective coating layer 18 shown in FIG. 1A is planarized until the LPC hard mask nitride layer 17 is exposed. At this point, the LPC hard mask nitride layer 17 and the organic anti-reflective coating layer 18 are dry etched using a gas containing a small amount of oxygen in which a fluorine-based gas is used as a basis gas. A reference numeral 18A represents the organic anti-reflective coating layer remaining after the dry etching.

Then, a sufficient over-etching is performed to overcome a thickness difference due to a specific topology and improve an open margin.

Referring to FIG. 1C, even if the remaining organic anti-reflective coating layer 18A shown in FIG. 1B and the LPC hard mask nitride layer 17 are appropriately over-etched, the LPC hard mask nitride layer 17A remains in a portion thicker than other portions. Also, a reference numeral 18B denotes the anti-reflective coating layer still remaining after this over-etching process. Therefore, a not-open event may result during an etching of the oxide layer.

FIGS. 2A to 2C are cross-sectional views for explaining the shoulder broken event in a conventional semiconductor device so as to prevent the limitations in FIGS. 1A to 1C.

Referring to FIG. 2A, a gate line is formed by stacking a gate oxide layer 22, gate conductive layers 23 and 24, and a gate hard mask 25 on a semiconductor substrate 21 where a device isolation layer (not shown) is formed.

At this point, the gate conductive layers are provided with a stack structure of a polysilicon layer 23 and a silicide layer 24. The gate hard mask 25, which is formed of nitride, is formed to 2,500 Å thick. However, the gate hard mask 25 of 2,100 Å thick remains after a gate patterning process.

Then, a CMP or etch-back process is performed to planarize the inter-layer insulating layer 26 by using the gate hard mask layer 25 as an etch target.

However, after the planarization, an indented portion is generated in the inter-layer insulating layer 26 between the gate lines due to a dishing event. The dishing event occurs when the gate line is over-etched in a wide contact hole region.

Then, an LPC hard mask nitride layer 27 and an organic anti-reflective coating layer 28 are deposited on an entire surface of the resulting structure. The LPC hard mask nitride layer 27 is deposited along the indented portion with step coverage. Since the organic anti-reflective coating layer 28 for the mask patterning is flowable, the inter-layer insulating layer 26 between the gate lines is thicker.

Referring to FIG. 2B, the organic anti-reflective coating layer 28 shown in FIG. 2A is planarized until the LPC hard mask nitride layer 27 is exposed. At this point, the LPC hard mask nitride layer 27 and the organic anti-reflective coating layer 28 are dry etched using a gas containing a small amount of oxygen in which a florin based gas is used as a basis gas. A reference numeral 28A denotes the organic anti-reflective coating layer remaining after the dry etching. Then, a sufficient over-etching is performed to overcome a thickness difference due to a specific topology and improve an open margin.

Referring to FIG. 2C, in order to prevent a LPC not-open event generally occurring when the LPC hard mask nitride layer 17 remains (refer to FIG. 1C), when an over-etching is performed on a region where the LPC hard mask nitride layer 27 and the remaining organic anti-reflective coating layer 28A are formed thickly, the gate hard mask layer 25 is over-etched so that its thickness is reduced, thereby reducing the LPC SAC margin. A reference numeral 25A represents the gate hard mask layer after the over-etching.

Also, the LPC hard mask nitride layer 27 and the gate hard mask layer 25 are the same SiₓN_{y}-based nitride layer that has the same etching rate under the same etching condition. Consequently, there occurs a loss of the gate hard mask nitride layer, which is denoted as a reference numeral 25A by the added over-etching for opening the LPC hard mask, thereby reducing the LPP isolation layer margin and SAC margin.

### SUMMARY OF THE INVENTION

It is, therefore, an object of the present invention to provide a method for fabricating a semiconductor device, capable of increasing a contact open margin and minimizing a shoulder loss of a gate line.

In accordance with an aspect of the present invention, there is provided a method for fabricating a semiconductor device, including: forming a gate line on a substrate, the gate line including a first hard mask and a second hard mask; forming an inter-layer insulating layer over the substrate and the gate line; stacking a contact mask and an anti-reflective coating layer on the inter-layer insulating layer, the contact mask defining a contact region; and etching the contact mask and the anti-reflective coating layer until the first and second hard masks are exposed.

### BRIEF DESCRIPTION OF THE DRAWINGS

The above and other objects and features of the present invention will become apparent from the following description of the preferred embodiments given in conjunction with the accompanying drawings, in which:

FIGS. 1A to 1C are cross-sectional views for explaining a not-open event of a conventional semiconductor device;

FIGS. 2A to 2C are cross-sectional views for explaining a shoulder broken of a conventional semiconductor device; and

FIGS. 3A to 3C are cross-sectional views illustrating a method for fabricating a semiconductor device in accordance with an embodiment of the present invention.

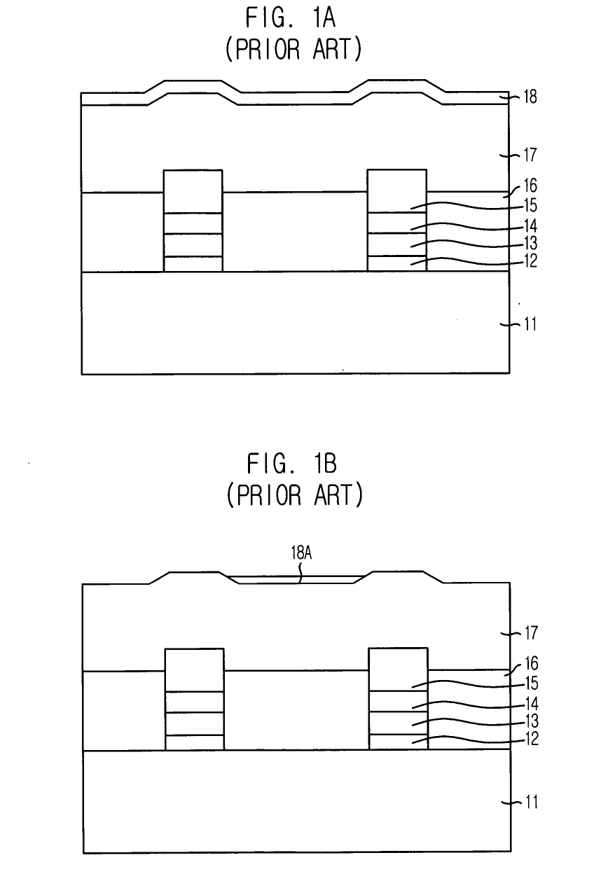

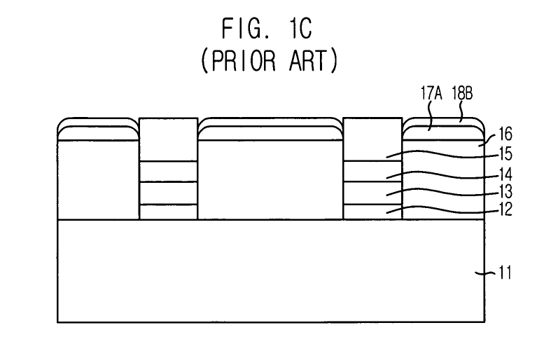

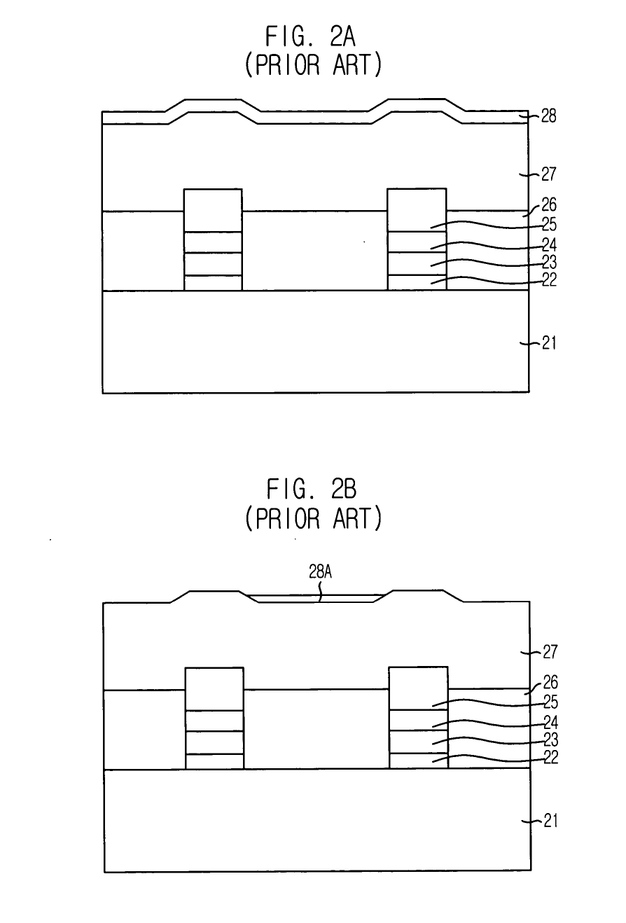

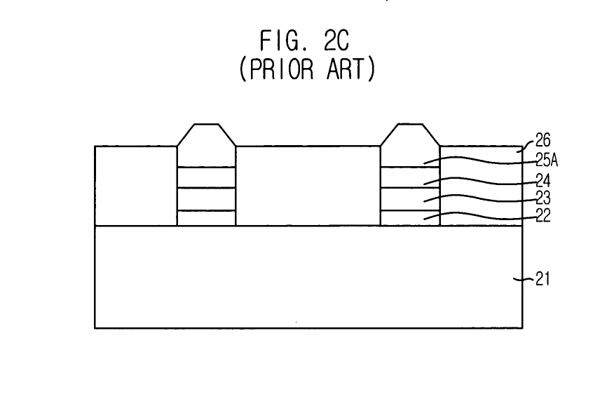

### DETAILED DESCRIPTION OF THE INVENTION

A method for fabricating a semiconductor device in accordance with exemplary embodiments of the present invention will be described in detail with reference to the accompanying drawings.

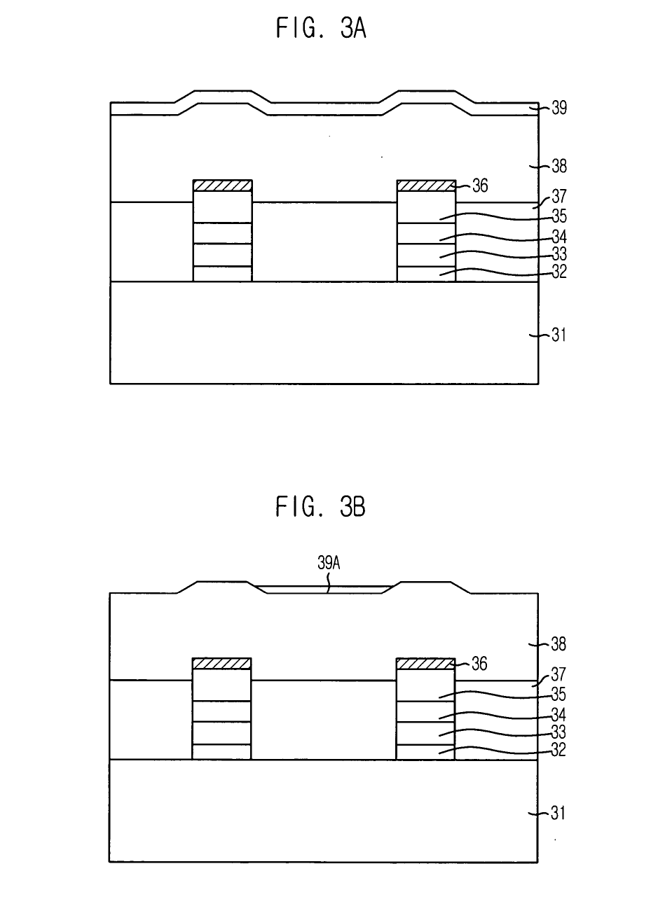

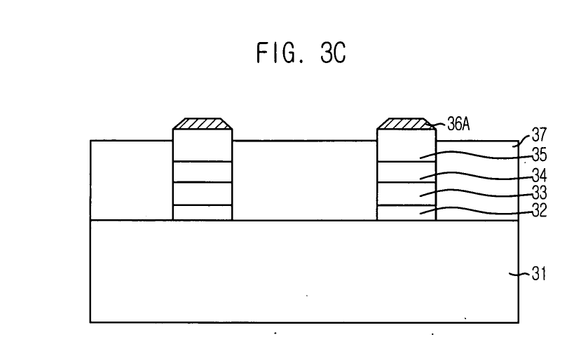

FIGS. 3A to 3C are cross-sectional views illustrating a method for fabricating a semiconductor device in accordance with an embodiment of the present invention.

Referring to FIG. 3A, a gate line is formed on a semiconductor substrate 11 where a device isolation layer (not shown) is formed. The gate line includes a gate oxide layer 32, gate conductive layers 33 and 34, a first gate hard mask 35, and a second gate hard mask 36, which are sequentially stacked on the semiconductor substrate 11.

Then, the first gate hard mask 35 is formed to approximately 1,500 A thick using a gas of SiH₄/NH₃/N₂, and the second gate hard mask 36 is formed to approximately 1,000 Å thick using a gas of SiH₄/N₂O/He. Although the present embodiment points out the specific thicknesses of the first gate hard mask 35 and the second gate hard mask 36, the first gate hard mask 35 and the second gate hard mask 36 can be formed to a certain range of thickness. For instance, the first gate hard mask 35 can be in a range from approximately 1,300 Å to approximately 1,600 Å. The second gate hard mask 36 can be in a range from approximately 900 Å to approximately 1,200 Å.

Also, the first gate hard mask 35 and the second gate hard mask 36 are deposited in-situ. However, a composition of the first gate hard mask 35 is different from that of the second gate hard mask 36.

More specifically, the first gate hard mask 35 is a pure nitride layer of Si—N bonds. The second gate hard mask 36 is deposited using N₂O gas or other oxygen containing gases. Therefore, the first gate hard mask 35 has a layer characteristic different from the second gate hard mask 36.

Then, a gate patterning process is performed until the first and second gate hard masks of approximately 2,100 Å remain. A thickness of an oxygen-containing nitride layer is approximately 600 Å out of the thickness of approximately 2,100 Å.

Meanwhile, the gate conductive layer has a stack structure of a polysilicon layer 33 and a silicide layer 34 and can also be formed of a tungsten layer, a tungsten silicide layer, a titanium layer, or a titanium nitride layer.

Then, a gap between the gate lines is filled by depositing an inter-layer insulating layer 37 on an entire surface of the above resulting substrate structure including the gate line. The inter-layer insulating layer 37 includes at least one layer selected from the group consisting of a borosilicate glass (BSG) layer, a borophosphosilicate glass (BPSG) layer, a phosphosilicate glass (PSG) layer, a tetraethyl orthosilicate (TEOS) layer, a high density plasma (HDP) oxide layer, a spin on glass (SOG) layer, and an advanced planarization layer (APL). Also, the inter-layer insulating layer 37 can be formed using an inorganic or organic based low-permittivity layer.

Then, a chemical mechanical polishing (CMP) process or an etch- back process is performed to planarize the inter-layer insulating layer 37 by using the second gate hard mask 36 as an etch target.

However, after the planarization, an indented portion is generated in the inter-layer insulating layer 37 between the gate lines due to a dishing event. The dishing event occurs when the gate line is over-etched in a wide contact hole region.

Then, an LPC hard mask layer 38 and an anti-reflective coating layer 39 are deposited on an entire surface of the resulting structure. The LPC hard mask layer 38 includes a nitride material, and the anti-reflective coating layer 39 includes an organic material. The LPC hard mask layer 38 is deposited along the indented portion with step coverage. Since the anti-reflective coating layer 39 for the mask patterning is flowable, the inter-layer insulating layer 37 between the gate lines is thicker.

As illustrated in FIG. 3B, the anti-reflective coating layer 39 (shown in FIG. 3A) and the LPC hard mask layer 38 are etched. A reference numeral 39A denotes the anti-reflective coating layer remaining after this etching process.

Table 1 shows an etching rate when the layers according to the present embodiment are etched using a florin-based gas in an radio frequency (RF)-plasma dry etching apparatus

TABLE 1

| | | | Oxygen-containing |
|---|---|---|---|
| | ER/min | Nitride | nitride |
| Etching rate (ER) | Å@Avg. | 2,820 | 1,560 |

It can be seen from Table 1 that an etch selectivity according to etching rates of a pure nitride layer (e.g., the LPC hard mask layer 38) and a layer containing oxygen impurities (e.g., the second hard mask 36) is approximately 1.8:1. That is, under the same etching condition, a small etching rate of the impurity containing layer is monitored. This result exhibits that the bond between Si-N lattices of the pure nitride layer is dissociated more easily than the Si—O—N bond. Also, the etch selectivity of the LPC hard mask layer 38 to the second hard mask 36 can range between approximately 3:1 and approximately 2:1

As illustrated in FIG. 3C, the remaining organic anti-reflective coating layer 39A and the LPC hard mask layer 38 are over-etched. While the over-etching process for the complete open of the LPC hard mask layer 38 is performed, the upper portion of the second gate hard mask layer 36 (refer to FIG. 3B) has a slower etching rate than the conventional gate hard mask layer. Compared with the conventional gate hard mask layer, the damage to the first gate hard mask layer 35 can be prevented. A reference numeral 36A denotes the second gate hard mask layer remaining after the over-etching process. Although not illustrated, the inter-layer insulation layer 37 is etched to form LPC contacts.

As described above, the etch loss of the inter-layer insulating layer can be prevented by stacking the gate hard mask layers with different composition ratios and etching the LPC hard mask layer. The height of the gate hard mask layer can be reduced and the operation margin for the inter-layer insulating layer can be improved. Also, the LPC contact open margin can be improved by the sufficient over-etching.

In addition, in order to increase the open contact margin by the over-etching of the LPC hard mask layer and to minimize the shoulder broken and the thickness loss of the gate hard mask layer, the uppermost layer of the gate hard mask layer and the LPC hard mask layer including a nitride material are etched at high etch selectivity under the same etch condition. Consequently, damage to the isolation layer can be prevented and the operation margin of the isolation layer can be improved. At the same time, the open margin of the LPC can be improved.

The present application contains subject matter related to the Korean patent application No. KR 2005-0056409, filed in the Korean Patent Office on Jun. 28, 2005, the entire contents of which being incorporated herein by reference.

While the present invention has been described with respect to the particular embodiments, it will be apparent to those skilled in the art that various changes and modifications may be made without departing from the scope of the invention as defined in the following claims.

What is claimed is:

1. A method for fabricating a semiconductor device, comprising:
forming a gate line on a substrate, the gate line including a first hard mask and a second hard mask;
forming an inter-layer insulating layer over the substrate and the gate line;
stacking a contact mask and an anti-reflective coating layer on the inter-layer insulating layer, the contact mask defining a contact region; and
etching the contact mask and the anti-reflective coating layer until the first and second hard masks are exposed.

2. The method of claim 1, wherein the contact mask has an etch selectivity with respect to the second hard mask.

3. The method of claim 2, wherein the etch selectivity of the contact mask to the second hard mask ranges between approximately 3:1 and approximately 2:1.

4. The method of claim 1, wherein the forming of the gate line includes:
stacking a gate oxide layer and a gate conductive layer;
forming the first hard mask to a first thickness; and
forming the second hard mask to a second thickness.

5. The method of claim 4, wherein the gate conductive layer has a stack structure of a polysilicon layer and a silicide layer.

6. The method of claim 4, wherein the first hard mask and the second hard mask are deposited in-situ.

7. The method of claim 1, wherein the first hard mask has a Si—N structure and the second hard mask has a Si—O—N structure.

8. The method of claim of claim 7, wherein the first hard mask is formed using a gas of SiH₄/NH₃/N₂.

9. The method of claim 8, wherein the first thickness is in a range from approximately 1,300 Å to approximately 1,600 Å.

10. The method of claim 7, wherein the second gate hard mask is formed using a gas of SiH₄/N₂O/He.

11. The method of claim 10, wherein the second thickness is in a range from approximately 900 Å to approximately 1,200 Å.

12. The method of claim 1, wherein the inter-layer insulating layer includes at least one layer selected from the group consisting of a borosilicate glass (BSG) layer, a borophosphosilicate glass (BPSG) layer, a phosphosilicate glass (PSG) layer, a tetraethyl orthosilicate (TEOS) layer, a high density plasma (HDP) oxide layer, a spin on glass (SOG) layer, and an advanced planarization layer (APL).

13. The method of claim 1, wherein the inter-layer insulating layer is formed using an inorganic or organic based low-permittivity layer.

14. The method of claim 1, wherein the inter-layer insulating layer is planarized using a chemical mechanical polishing (CMP) process or an etch-back process.

15. The method of claim 1, further comprising etching the inter-layer insulating layer to form a hole.
